(19) United States
(12) Patent Application Publication
(10) Pub. No.: US 2024/0414840 A1
(43) Pub. Date: Dec. 12, 2024

(54) GLASS CLOTH, PREPREG AND PRINTED WIRING BOARD

(71) Applicant: ASAHI KASEI KABUSHIKI KAISHA, Tokyo (JP)

(72) Inventors: Amane HIROSE, Tokyo (JP); Yuka FUKAYA, Tokyo (JP)

(73) Assignee: ASAHI KASEI KABUSHIKI KAISHA, Tokyo (JP)

(21) Appl. No.: 18/699,512

(22) PCT Filed: Oct. 5, 2022
(86) PCT No.: PCT/JP2022/037310

§ 371 Date: Apr. 8, 2024

(30) Foreign Application Priority Data
Oct. 8, 2021 (JP) 2021-166225

(51) Int. Cl. H05K 1/03; D03D 15/267; D06M 13/513

(52) U.S. Cl. CPC H05K 1/038; D03D 15/267; D06M 13/513; H05K 1/0306; D10B 2101/06

(57) ABSTRACT

The present disclosure relates to a glass cloth, a prepreg, and a printed circuit board. There is provided a glass cloth, comprising woven glass yarns, wherein a bulk dissipation factor of a glass constituting the glass yarns is 0.0010 or less, a loss on ignition value of the glass cloth is 0.01% by mass or more and less than 0.12% by mass, and a void number five minutes later is 180 or less, when the glass cloth is impregnated with castor oil.

### FIELD

The present invention relates to a glass cloth, a prepreg, and a printed circuit board.

### BACKGROUND

Currently, the performance of information terminals such as smartphones is increasing, and high-speed communication as exemplified by 5G communication is progressing. In accordance with such circumstances, in particular, in the case of printed circuit boards for high-speed communication, it is desired not only to improve the heat resistance, which has been conventionally required, but also to further improve the dielectric properties of the insulating materials (for example, lowering the dissipation factor). Similarly, there is also demand for improving the dielectric properties of a prepreg used as an insulating material for printed circuit boards, as well as the glass yarns and glass cloth contained in the prepreg.

In order to lower the dielectric constant of an insulating material, a method for constructing the insulating material using a prepreg of a glass cloth impregnated with a low-dielectric resin (hereinafter referred to as “matrix resin”) is known (Patent Literature 1 and 2). Patent Literature 1 and 2 describe that a polyphenylene ether terminally-modified with a vinyl group or methacryloxy group is advantageous in low-dielectric properties and heat resistance, and describe the use of this modified polyphenylene ether as a matrix resin.

Furthermore, in order to improve the dielectric properties of a prepreg, a method for constructing the prepreg using a low-dielectric glass is also known (Patent Literature 3). In Patent Literature 3, glass yarns having an SiO₂ composition amount of 98% by mass to 100% by mass are used. Patent Literature 3 describes a method for constructing a prepreg using a low-dielectric glass cloth which has been surface-treated with a silane coupling agent having a double bond group and which meets various requirements such as a loss on ignition value of 0.12% by mass to 0.40% by mass. Furthermore, as coupling agents, for example, aminosilane and aminosilane hydrochloride are known (Patent Literature 4).

Further, Patent Literature 5 and 6 report a technology for opening a glass cloth using water pressure such as a water jet, and a technology for opening a glass cloth using ultrasonic waves. By subjecting a glass cloth to an opening treatment, the generation of air bubbles referred to as voids present in prepregs and printed circuit boards can be suppressed. It is known that the opening treatment step is important in the production steps of a glass cloth because the heat resistance and insulation properties of the printed circuit board can be improved by reducing the number of voids.

### CITATION LIST

### Patent Literature

[PTL 1] WO 2019/065940
[PTL 2] WO 2019/065941
[PTL 3] Japanese Unexamined Patent Publication (Kokai) No. 2018-127747
[PTL 4] Japanese Unexamined Patent Publication (Kokai) No. 2016-98135
[PTL 5] Japanese Unexamined Patent Publication (Kokai) No. 2009-263824
[PTL 6] Japanese Unexamined Patent Publication (Kokai) No. 2020-158945

### SUMMARY

### Technical Problem

However, Patent Literature 1 and 2 have room for consideration from the viewpoint of further improving dielectric properties. For example, Patent Literature 1 and 2 do not consider the use of a low-dielectric glass as described in Patent Literature 3. Furthermore, Patent Literature 3 describes that glasses having a SiO₂ composition amount of 98% by mass to 100% by mass are problematic from a practical viewpoint, and thus, the provision of other methods for suitably providing a glass cloth and a prepreg using this type of glass yarns has been awaited.

Furthermore, when aminosilane or aminosilane hydrochloride described in Patent Literature 6 is used as a silane coupling agent, there are problems in that peeling tends to occur at the interface between the glass cloth and the matrix resin, and as a result, it tends to be difficult to secure various properties. Furthermore, there was room for consideration in the glass cloth described in Patent Literature 4 from the viewpoint of further improving dielectric properties. In other words, a new method for lowering the dissipation factor of a glass cloth, which is different from the method for decreasing silanol groups present on the surface of the glass cloth as explained in Patent Literature 4, has been awaited.

It has been revealed by the inventors that since quartz glass has a higher hardness than other glasses, a glass cloth composed of quartz glass yarns cannot be sufficiently opened by the conventional opening treatment described in Patent Literature 5 and 6.

An object of the present invention is to provide a glass cloth and a prepreg which allow for suitably obtaining the advantages of a low-dielectric glass such as quartz glass cloth and a surface treatment of glass yarns using a specific silane coupling agent and for improving dielectric properties (for example, lowering a dissipation factor). Another object of the present invention is to provide a printed circuit board, an integrated circuit, and an electronic device which allow for improving insulation reliability and heat resistance by using a glass cloth which has been processed to have a higher opening than in the prior art. Yet another object of the present invention is to provide a glass treatment method by which the glass cloth described above can suitably be obtained.

### Solution to Problem

As a result of rigorous investigation in order to solve the above problems, in the case of using a low-dielectric glass for glass yarns, the present inventors arrived at focusing on the type and amount of the silane coupling agent chemically bonded to the surface of the glass. It was then discovered that by controlling the type and amount of the silane coupling agent chemically bonded to the glass surface, it is possible to suitably lower the dissipation factor of the glass cloth while securing the heat resistance of the resulting printed circuit board. The present inventors also discovered that by subjecting the glass cloth to an opening treatment using, for example, dry ice blasting, it is possible to improve the insulation reliability and heat resistance of the printed circuit board while decreasing the adhesion amount of silane coupling agent, and have completed the present invention. Some of the aspects of the present invention are illustrated below.

[1]

A glass cloth, comprising woven glass yarns, wherein
a bulk dissipation factor of a glass constituting the glass yarns is 0.0010 or less,
a loss on ignition value of the glass cloth is 0.01% by mass or more and less than 0.12% by mass, and
a void number five minutes later is 180 or less, when the glass cloth is impregnated with castor oil.
   [2]

The glass cloth according to Item 1, wherein a void reduction rate from one minute later to five minutes later is 70% or more, when the glass cloth is impregnated with castor oil.

[3]

A glass cloth, comprising woven glass yarns, wherein
a bulk dissipation factor of a glass constituting the glass yarns is 0.0010 or less,
a loss on ignition value of the glass cloth is 0.01% by mass or more and less than 0.12% by mass, and
a void reduction rate from one minute later to five minutes later is 70% or more, when the glass cloth is impregnated with castor oil.
   [4]

The glass cloth according to Item 1 or 2, wherein a void number five minutes later is 160 or less, when the glass cloth is impregnated with castor oil.

[5]

The glass cloth according to Item 2 or 3, wherein a void reduction rate from one minute later to five minutes later is 80% or more, when the glass cloth is impregnated with castor oil.

[6]

The glass cloth according to any one of Items 1 to 5, wherein the bulk dissipation factor of the glass constituting the glass yarns is 0.0008 or less.

[7]

The glass cloth according to any one of Items 1 to 6, wherein a silicon (Si) content of the glass yarns is 95.0% by mass to 100% by mass in terms of silicon dioxide (SiO₂).

[8]

The glass cloth according to any one of Items 1 to 7, wherein a silicon (Si) content of the glass yarns is 99.0% by mass to 100% by mass in terms of silicon dioxide (SiO₂).

[9]

The glass cloth according to any one of Items 1 to 8, which has been subjected to a surface treatment.

[10]

The glass cloth according to Item 9, wherein the surface treatment is a treatment with a silane coupling agent having a structure represented by the following general formula (1):

X(R)₃₋ₙSiYₙ (1)
where X is an organic functional group having one or more radical-reactive unsaturated double bond groups,
each Y is independently an alkoxy group,
n is an integer from 1 to 3, and
each R is independently at least one group selected from the group consisting of a methyl group, an ethyl group, and a phenyl group.
   [11]

The glass cloth according to Item 10, wherein X in general formula (1) does not contain an amino group and contains a (meth)acryloxy group.

[12]

The glass cloth according to any one of Items 1 to 11, wherein a loss on ignition value of the glass cloth is 0.10% by mass or less.

[13]

The glass cloth according to any one of Items 1 to 12, wherein a nitrogen content per mass is less than 0.004% by mass.

[14]

The glass cloth according to any one of Items 1 to 13, wherein a dissipation factor of the glass cloth at 10 GHz as measured by a resonance method is greater than 0 and 0.0008 or less.

[15]

The glass cloth according to any one of Items 1 to 14, wherein a dissipation factor of the glass cloth at 10 GHz as measured by a resonance method is greater than 0 and 0.0005 or less.

[16]

A prepreg, comprising the glass cloth according to any one of Items 1 to 15, and a matrix resin with which the glass cloth is impregnated.

[17]

The prepreg according to Item 16, further comprising an inorganic filler.

[18]

A printed circuit board, comprising the prepreg according to Item 16 or 17.

[19]

An integrated circuit, comprising the printed circuit board according to Item 18.

[20]

An electronic device, comprising the printed circuit board according to Item 18.

### Advantageous Effects of Invention

According to the present invention, there can be provided a glass cloth and a prepreg which allow for suitably obtaining the advantages of a low-dielectric glass and a surface treatment of glass yarns using a specific silane coupling agent and for improving dielectric properties (for example, lowering a dissipation factor). Furthermore, according to the present invention, by using the prepreg, there can be provided a printed circuit board, an integrated circuit, and an electronic device which allow for improving heat resistance.

### DESCRIPTION OF EMBODIMENTS

Embodiments of the present invention (hereinafter referred to as the “present embodiment”) will be described below, but the present invention is not limited thereto, and various changes can be made without deviating from the spirit of the present invention.

In the present embodiment, numerical ranges described using “to” represent numerical ranges including the numerical values before and after “to” as the lower limit and upper limit thereof, respectively. Furthermore, in the present embodiment, in numerical ranges described in stages, the upper limit or lower limit described in a certain numerical range can be replaced with the upper limit or lower limit of another numerical range described in stages. Furthermore, in the present embodiment, the upper limit value or lower limit value described in a certain numerical range can be replaced with the values shown in the Examples. In the present embodiment, the term “step” includes not only independent steps but also steps which cannot be clearly distinguished from other steps, as long as the purpose of the step is achieved.

### [Glass Cloth]

### [Overall Structure]

The glass cloth according to the present embodiment is a glass cloth comprising woven glass yarns, wherein a bulk dissipation factor of a glass constituting the glass yarns is 0.0010 or less, a loss on ignition value of the glass cloth is 0.01% by mass or more and less than 0.12% by mass, and a void number five minutes later is 180 or less, when the glass cloth is impregnated with castor oil. Further, it is preferable that a void reduction rate from one minute later to five minutes later be 70% or more, when the glass cloth is impregnated with castor oil.

Furthermore, a second glass cloth according to the present embodiment is a glass cloth comprising woven glass yarns, wherein a bulk dissipation factor of a glass constituting the glass yarns is 0.0010 or less, a loss on ignition value of the glass cloth is 0.01% by mass or more and less than 0.12% by mass, and a void reduction rate from one minute later to five minutes later is 70% or more, when the glass cloth is impregnated with castor oil.

Note that it is preferable that the void number five minutes later be 160 or less, when the glass cloth is impregnated with castor oil, and that the void reduction rate from one minute later to five minutes later be 80% or more, when the glass cloth is impregnated with castor oil.

According to this, there can be provided a glass cloth and a prepreg which allow for improving dielectric properties (for example, lowering a dissipation factor) and improving heat resistance and insulation reliability of a printed circuit board. According to the present embodiment, a glass cloth having a dissipation factor close to the bulk dissipation factor of the glass can be obtained.

The glass cloth according to the present embodiment can comprise woven glass yarns (for example, glass yarns composed of a plurality of glass filaments) as warp and weft yarns. Examples of the weave structure of the glass cloth include weave structures such as plain weave, basket weave, satin weave, and twill weave. Among these, the plain weave structure is preferable.

The warp and weft yarns constituting the glass cloth according to the present embodiment preferably have a weave density of 10 yarns/inch to 120 yarns/inch (=10 to 120 yarns/25.4 mm), and more preferably 40 yarns/inch to 100 yarns/inch. When the weave density is within the above range, the effects of the present invention can easily be obtained.

The basis weight of the glass cloth (mass of the glass cloth) according to the present embodiment is preferably 8 g/m² to 250 g/m², more preferably 8 g/m² to 100 g/m², more preferably, 8 g/m² to 80 g/m², and particularly preferably 8 g/m² to 50 g/m². When the basis weight of the glass cloth is within the above range, the effects of the present invention can easily be obtained.

### [Glass Yarns]

The glass yarns constituting the glass cloth according to the present embodiment are obtained using a low-dielectric glass as a raw material. Specifically, the glass yarns have a bulk dissipation factor of 0.0010 or less. By using such glass yarns, it is possible to improve the dielectric properties of the resulting glass cloth. From the viewpoint of improving the dielectric properties of the resulting glass cloth, the bulk dissipation factor of the glass is preferably 0.0008 or less, more preferably 0.0006 or less, further preferably 0.0005 or less, and particularly preferably 0.0003 or less.

The glass yarns having a bulk dissipation factor of 0.0010 or less preferably have a Si content, in terms of SiO₂, in the range of 95.0% by mass to 100% by mass, more preferably 99.0 to 100% by mass, further preferably 99.5 to 100% by mass, and particularly preferably 99.9 to 100% by mass. By using such glass yarns, it is possible to improve the dielectric properties of the resulting glass cloth.

The bulk dissipation factor of the glass constituting the glass cloth of the present embodiment is in the range of 0.0010 or less, more preferably in the range of 0.0008 or less, further preferably in the range of 0.0005 or less, and particularly preferably in the range of 0.0004 or less. The bulk dissipation factor of the glass constituting the glass cloth can be measured by the method described in the Examples.

The average filament diameter of the glass filaments constituting the glass yarns is preferably 2.5 μm to 9.0 μm, more preferably 2.5 μm to 7.5 μm, further 3.5 μm to 7.0 μm, even further preferably 3.5 μm to 6.0 μm, and particularly preferably 3.5 μm to 5.0 μm. When the filament diameter is less than the above value, the breaking strength of the filament will be low, whereby the resulting glass cloth is likely to be fluffy. When the filament diameter exceeds the above value, the mass of the glass cloth increases, making transportation and processing difficult. When the average filament diameter of the glass filament is within the above range, the effects of the present invention can easily be obtained.

In the glass cloth according to the present embodiment, it is preferable that the glass yarns have been subjected to a surface treatment from the viewpoint of improving adhesion with the resin used for the prepreg. The glass yarns can be subjected to a surface treatment with, for example, a titanate coupling agent or a silane coupling agent, and preferably a surface treatment with a silane coupling agent from the viewpoint of ease of modifying suitable functional groups for each prepreg resin.

The nitrogen content per mass of the glass cloth is preferably less than 0.004% by mass. Such nitrogen content is based on, for example, the amount of components containing amino groups in the silane coupling agent. Note that the nitrogen content per mass of the glass cloth may be 0 or more.

### [Silane Coupling Agent]

The silane coupling agent used in the present embodiment preferably has a structure represented by the following general formula (1):

X(R)₃₋ₙSiYₙ (1)
where X is an organic functional group having one or more radical-reactive unsaturated double bond groups,
each Y is independently an alkoxy group,
n is an integer from 1 to 3, and
each R is independently a group selected from the group consisting of a methyl group, an ethyl group, and a phenyl group.

By subjecting the glass cloth to a surface treatment with the silane coupling agent of general formula (1), it becomes easier to improve the insulation reliability and heat resistance of the printed circuit board.

Furthermore, it is preferable that X in the molecular structure of a silane coupling agent of general formula (1) contain a (meth)acryloxy group without containing an amino group. Silane coupling agents containing a very small amount of a component containing an amino group or containing no amino group have high hydrophobicity. By subjecting the glass yarns, which are composed of a low-dielectric glass, to a surface treatment with such a highly hydrophobic silane coupling agent, peeling at the interface between the resulting glass cloth and matrix resin can be suppressed, and as a result, various properties including dielectric properties (for example, insulation properties) can be improved. Furthermore, in the present description, the concept of glass yarns having been subjected to a surface treatment with a silane coupling agent encompasses both the case in which the glass filament has been subjected to a surface treatment with a silane coupling agent and the case in which the glass cloth has been subjected to a surface treatment with a silane coupling agent. The method for evaluating whether an amino group is contained is not particularly limited, and methods using gas chromatography are known. By measuring the amount of nitrogen dioxide generated by thermal decomposition using gas chromatography, it is possible to determine whether the silane coupling agent contains an amino group. Specifically, if the nitrogen content per mass of the glass cloth is less than 0.004% by mass, it can be determined that the silane coupling agent does not contain amino groups. Note that the nitrogen content per mass of the glass cloth may be 0 or more. If the silane coupling agent contains an extremely small amount of a component containing an amino group or does not contain such a component, depending on the measurement method, due to disturbances in the baseline, etc., the “content of components containing amino groups in the silane coupling agent” and, by extension, the “nitrogen content per mass of the glass cloth”, may be derived as negative values. However, in this case as well, the nitrogen content per mass of the glass cloth falling under the meaning of a trace amount is included in the concept of “less than 0.004% by mass.”

The present inventors speculate that one of the causes of increase in the dissipation factor of a glass cloth is unnecessary components that remain physically adhered to the surface of glass yarns without forming chemical bonds. Examples of unnecessary components include residues or denatured products of the silane coupling agent that remain physically adhered to the surface of the glass yarns without forming chemical bonds and cannot be washed out completely. From the viewpoint of suppressing the remainder and generation (denaturation) of unnecessary components which should originally be decreased from the surface of glass yarns, it is preferable that X in general formula (1) be an organic functional group having one or more radical-reactive unsaturated double bond groups which does not contain an amino group.

X in general formula (1) does not contain an amino group. For example, X in general formula (1) preferably does not contain amines such as primary amines, secondary amines, tertiary amines, or ammonium cations such as quaternary ammonium cations. As a result, the amount of the silane coupling agent chemically bonded to the surface of the glass yarns can be suitably controlled, whereby the dielectric properties of the glass cloth can be suitably improved. Furthermore, the heat resistance of the resulting printed circuit board can also be secured.

In order to stabilize the glass cloth, it is preferable that at least one of the plural Y present in general formula (1) be an alkoxy group having 1 to 5 carbon atoms (an alkoxy group having 1, 2, 3, 4, or 5 carbon atoms). It is more preferably that half or more or all of the plural Y be alkoxy groups having 1 or more and 5 or fewer carbon atoms.

The silane coupling agent represented by general formula (1) may be used alone or in combination of two or more. For example, two or more silane coupling agents different from each other in X in general formula (1) may be used together, or two or more silane coupling agents different from each other in R in general formula (1) may be used together.

The content derived from the silane coupling agent represented by general formula (1) in the silane coupling agent for a surface treatment of the glass yarns is preferably 95.0% by mass to 100% by mass, more preferably 96.5% by mass to 100% by mass, further preferably 98.0% by mass to 100% by mass, even further preferably 99.0% by mass to 100% by mass, and particularly preferably 99.9% by mass to 100% by mass. According to this, it becomes easier to improve various properties including the dielectric properties of the resulting glass cloth. The silane coupling agent used in the present embodiment may include a silane coupling agent (other silane coupling agent) other than the silane coupling agent represented by general formula (1), and may contain components other than the silane coupling agent within the scope of the present invention.

The molecular weight of the silane coupling agent represented by general formula (1) is preferably 100 to 600, more preferably 150 to 500, and further preferably 200 to 450. Among these, it is preferable to use a plurality of silane coupling agents having mutually different molecular weights within the above range as the silane coupling agent. According to this, the glass yarns can be suitably subjected to a surface treatment with different types of silane coupling agents, whereby the density of the silane coupling agents on the glass surface increases. As a result, the reactivity with the matrix resin tends to be further improved. When using a plurality of silane coupling agents with different molecular weights, it is preferable that at least two of the silane coupling agents be silane coupling agents represented by general formula (1) and within the molecular weight range described above.

The silane coupling agent represented by general formula (1) is preferably nonionic. For example, X in general formula (1) preferably has at least one group selected from the group consisting of a vinyl group and a (meth)acryloxy group, and more preferably a (meth)acryloxy group. According to this, suitable reactivity with the matrix resin can be secured, whereby the heat resistance and reliability of the printed circuit board can easily be improved. Note that the (meth)acryloxy group includes at least one of a methacryloxy group and an acryloxy group.

As the silane coupling agent represented by general formula (1), for example, vinyltrimethoxysilane, 3-methacryloxypropyltrimethoxysilane, 5-hexenyltrimethoxysilane, and acryloxypropyltrimethoxysilane are preferable. According to these silane coupling agents, the effects of the present invention can easily be obtained. In addition thereto, examples of the silane coupling agent represented by general formula (1) include the following silane coupling agents.

TABLE 1

| X | Y | n | R |
|---|---|---|---|
| Vinyl group | 1, 2, 3, 4, or 5 | 1 | At least one of methyl group, ethyl |
| | carbon atoms | | group, and phenyl group |
| Vinyl group | 1, 2, 3, 4, or 5 | 2 | At least one of methyl group, ethyl |
| | carbon atoms | | group, and phenyl group |
| Vinyl group | 1, 2, 3, 4, or 5 | 3 | At least one of methyl group, ethyl |
| | carbon atoms | | group, and phenyl group |
| Methacryloxy | 1, 2, 3, 4, or 5 | 1 | At least one of methyl group, ethyl |
| group | carbon atoms | | group, and phenyl group |
| Methacryloxy | 1, 2, 3, 4, or 5 | 2 | At least one of methyl group, ethyl |
| group | carbon atoms | | group, and phenyl group |
| Methacryloxy | 1, 2, 3, 4, or 5 | 3 | At least one of methyl group, ethyl |
| group | carbon atoms | | group, and phenyl group |
| Acryloxy group | 1, 2, 3, 4, or 5 | 1 | At least one of methyl group, ethyl |
| | carbon atoms | | group, and phenyl group |
| Acryloxy group | 1, 2, 3, 4, or 5 | 2 | At least one of methyl group, ethyl |
| | carbon atoms | | group, and phenyl group |
| Acryloxy group | 1, 2, 3, 4, or 5 | 3 | At least one of methyl group, ethyl |
| | carbon atoms | | group, and phenyl group |

### [Loss on Ignition Value of Glass Cloth]

The glass cloth according to the present embodiment has a loss on ignition value of 0.01% by mass or more and less than 0.12% by mass. According to this, a printed circuit board having suitable insulation properties and a lower dissipation factor can be provided. The loss on ignition value is an index from which the amount of silane coupling agent on the glass cloth in a surface treatment can indirectly be determined, and can be measured in accordance with the method described in JIS R3420.

The loss on ignition value of the glass cloth is preferably 0.01% by mass or more and 0.10% by mass or less, more preferably 0.02% by mass or more and 0.09% by mass or less, and further preferably 0.03% by mass or more and 0.08% by mass or less. When the loss on ignition value exceeds the above value, the amount of silane coupling agent chemically bonded to the surface of the glass yarn tends to be excessively large, and in this case, the dissipation factor of the glass cloth, and by extension, the dissipation factor of the resulting printed circuit board, tends to be lowered. Conversely, when the loss on ignition value is less than the above value, the amount of silane coupling agent bonded to the surface of the glass yarns tends to be excessively small, and in this case, the heat resistance of the resulting printed circuit board is likely to be reduced.

In this regard, in the present embodiment, as described above, a low-dielectric glass is used as the glass yarns, and it is preferable that the nitrogen content per mass of the glass cloth be less than 0.004% by mass, more preferably less than 0.0035, further preferably less than 0.003, and particularly preferably less than 0.0025. It is generally indicated that glass cloths using a low-dielectric glass are prone to brittle fracture due to the high hardness of SiO₂. However, the risk of brittle fracture of the glass cloth of the present embodiment can be reduced due to suitable compatibility between the low-dielectric glass and the silane coupling agent for the surface treatment thereof, as well as the loss on ignition value of the glass cloth within the above range.

### [Method for Measuring Dissipation Factor of Glass Cloth]

The dielectric properties of the glass cloth according to the present embodiment can be measured using the resonance method. A split cylinder resonator is a preferable measurement device using the resonance method. According to the resonance method, measurements can be made more easily and accurately than conventional measurement methods in which a printed circuit board as a measurement sample is produced and the dielectric properties are evaluated. The reason for this is, although not to be bound by theory, that the resonance method is suitable for evaluating low-loss materials in high-frequency range. In addition to the resonance method, the lumped parameter method and the reflection transmission method are known as evaluation methods of dielectric properties. In the lumped parameter method, it is necessary to form a capacitor by interposing a measurement sample between two electrodes, and as a result, there is a problem in that the operation is very complicated. The reflection transmission method has a problem in that it is difficult to evaluate the dissipation factor of a sample with high accuracy when evaluating a low-loss material because of the strong influence of port matching characteristics.

When measuring the dielectric properties of the glass cloth according to the present embodiment, which is applicable to printed circuit boards, and in particular, printed circuit boards for high-speed communication, the measurable range of the measuring device is preferably a suitable range for both the frequency permittivity (Dk) and the dissipation factor (Df). For example, Dk is preferably in the range of 1.1 Fm⁻¹ to 50 Fm⁻¹, more preferably in the range of 1.5 Fm⁻¹ to 10 Fm⁻¹, and further preferably in the range of 2.0 Fm⁻¹ to 5 Fm⁻¹. Further, Df is preferably in the range of 1.0×10⁻⁶ to 1.0×10⁻¹, more preferably in the range of 1.0×10⁻⁵ to 5.0×10⁻¹, and further preferably in the range of 5.0×10⁻⁵ to 1.0×10⁻².

It is preferable that the measurable frequency of the measuring device be 10 GHz or more. When the frequency is 10 GHz or more, it is possible to perform characteristic evaluation in the frequency band region expected when the glass cloth is actually used as a printed circuit board for high-speed communication.

The measurement area is preferably 10 mm² or more, more preferably 15 mm² or more, and further preferably 20 mm² or more. By measuring the dielectric properties of the glass cloth over a larger measurement area, the reliability of test results for the glass cloth can be increased.

The measurable thickness of the sample is preferably 3 μm to 300 μm, more preferably 5 μm to 200 μm, and further preferably 7 μm to 150 μm. According to this, the reliability of the test results for the glass cloth can be increased.

It is possible to have a rough estimate of the dissipation factor of the glass cloth from the bulk dissipation factor, and vice versa. Conversely, the dissipation factor of the glass cloth may sometimes be different from the bulk dissipation factor. The reasons for this difference, although not to be bound by theory, include, for example, (1) the generation of thermal oxides and degradation products of the sizing agent physically adhered to the surface of glass yarns, and (2) the remainder and generation of unnecessary components physically adhered to the surface of glass yarns without forming chemical bonds and which cannot be washed out completely. Thus, the dissipation factor of the glass cloth can be controlled within the above range by selecting the type of the sizing agent and optimizing various conditions in the glass cloth production process.

In the glass cloth according to the present embodiment, the dissipation factor at 10 GHz as measured by the resonance method described above is preferably 0.0008 or less, more preferably 0.0005 or less, further preferably 0.00045 or less, even further preferably 0.000425 or less, and particularly preferably 0.0004 or less. With such a glass cloth, a prepreg which can improve dielectric properties can be provided.

### [Impregnation Properties of Glass Cloth]

A first glass cloth according to the present embodiment has a void number five minutes later of 180 or less, when the glass cloth is impregnated with castor oil. According to this, since the glass cloth has suitable impregnation properties with the resin, the insulation properties and heat resistance of the printed circuit board can be improved. The number of voids five minutes later is preferably 160 or less, more preferably 140 or less, further preferably 120 or less, even further preferably 110 or less, and particularly preferably 100 or less. The smaller the number of voids five minutes later, the better the impregnation properties and the stronger the adhesion between the glass cloth and the resin becomes. Thus, even if the amount of surface treatment agent adhered to the surface of glass cloth is small, a printed circuit board having suitable insulation reliability and heat resistance can be provided. The void number five minutes later to 180 or less when the glass cloth is impregnated with castor oil can be achieved, for example, by treating the glass cloth with the silane coupling agent represented by general formula (1) above and using an opening method such as dry ice blasting processing or bending processing.

The first glass cloth according to the present embodiment preferably has a void reduction rate from one minute later to five minutes later of 70% or more, when the glass cloth is impregnated with castor oil. Further, the range is preferably 80% or more, more preferably 82% or more, further preferably 84% or more, even further preferably 86% or more, and particularly preferably 88% or more. The number of voids can be measured by the method described in the Examples.

A second glass cloth according to the present embodiment has a void reduction rate from one minute later to five minutes later of 70% or more, when the glass cloth is impregnated with castor oil. According to this, since the glass cloth has suitable impregnation properties with the resin, the insulation properties and heat resistance of the printed circuit board can be improved. The void reduction rate from one minute later to five minutes later is preferably in the range of 80% or more, more preferably in the range of 82% or more, further preferably in the range of 84% or more, even further preferably in the range of 86% or more, and particularly preferably in the range of 88% or more. The higher void reduction rate from one minute later to five minutes later means that in the step of impregnating the resin as a varnish on glass cloth and in the step of processing a printed circuit board from a prepreg by heating and pressurizing, the voids in the glass cloth yarn bundle can more easily be removed, whereby the adhesion between the glass cloth and the resin can be improved. By improving the adhesion between the glass cloth and the resin, a printed circuit board which has suitable insulation reliability and heat resistance even if the amount of surface treatment agent adhered to the surface of the glass cloth is small can be provided. The void reduction rate from one minute later to five minutes later of 70% or more, when the glass cloth is impregnated with castor oil can be achieved, for example, by treating the glass cloth with the silane coupling agent represented by general formula (1) above, and using an opening method such as dry ice blasting processing or bending processing. The void reduction rate can be measured by the method described in the Examples.

### [Method for Production of Glass Cloth]

A first method for the production of the glass cloth according to the present embodiment includes a glass processing method.

The glass processing method according to the present embodiment comprises:
a step (A) of decreasing a sizing agent from glass yarns having a bulk dissipation factor of 0.0010 or less;
a step (B) of decreasing a silane coupling agent from the glass cloth so that the loss on ignition value is 0.01% by mass or more and less than 0.12% by mass; and
a step (C) of subjecting the glass cloth to an opening treatment so that a void number five minutes later is 180 or less, when the glass cloth is impregnated with castor oil.

As a result, a glass cloth and prepreg which can improve the dielectric properties and heat resistance of a printed circuit board can be provided.

A second method for the production of the glass cloth according to the present embodiment includes a glass processing method.

The glass processing method according to the present embodiment comprises:
a step (A) of decreasing a sizing agent from glass yarns having a bulk dissipation factor of 0.0010 or less;
a step (B) of decreasing a silane coupling agent from the glass cloth so that the loss on ignition value is 0.01% by mass or more and less than 0.12% by mass; and
a step (C) of subjecting the glass cloth to an opening treatment so that a void reduction rate from one minute later to five minutes later is 70% or more, when the glass cloth is impregnated with castor oil.

As a result, a glass cloth and prepreg which can improve the dielectric properties and heat resistance of a printed circuit board can be provided.

The glass processing method according to the present embodiment can be applied to the glass yarns and also to the glass cloth. In other words, the step of weaving glass yarns to obtain a glass cloth may be provided before, during, or after the glass processing method according to the present embodiment. In addition, in the glass processing method according to the present embodiment, “decreasing” means, for example, removing at least a part of the sizing agent or the silane coupling agent, and allows for the occurrence of residual material that could not be completely removed.

Step (A) of decreasing the sizing agent can include, for example:
a de-sizing step (heating de-oiling step) in which the glass is heated at a temperature of 650° C. to 1000° C. As a result, it is easier to decrease the sizing agent from the glass. By decreasing the small amount of thermal oxidation degradation products of the sizing agent which remain physically adhered to the glass surface, it becomes easier to effectively suppress an increase in the dissipation factor of the resulting glass cloth.

Heating of the glass cloth can be carried out sequentially or continuously, in a closed system or in an open system, or in a combination of closed and open systems. From the viewpoint of productivity, it is particularly preferable to heat-treat the glass cloth in a roller-to-roller manner using a device having an unwinding mechanism and a winding mechanism.

In the case of a closed system, from the viewpoint of the heating means, it is preferable to place the glass cloth in a heating furnace, and/or from the viewpoint of storage space and heating range, it is preferable that the glass cloth be heated while being stored in the form of a roll. From the viewpoint of increasing the efficiency of organic matter removal and shortening the time for removing organic matter, it is also preferable that the glass cloth be heated while being conveyed in a heating furnace.

In the case of an open system, from the viewpoint of the area to be heated, it is preferable that the glass cloth be heated while being transported. The glass cloth can be transported by, for example, an unwinding mechanism and a winding mechanism.

### [Heating Furnace]

A heating means for the heating furnace is not limited to a specific means, and various heaters such as electric heaters and burners can be used as long as the surface temperature of the glass cloth can be heated to a temperature higher than 650° C. Although heating may be performed by combining a plurality of means, it is preferable to heat the glass cloth in an atmosphere with an oxygen concentration of 10% or more, and thus, it is preferable to use a gas single radiant tube burner or an electric heater.

From the viewpoint of heating efficiency, the heating furnace preferably comprises means for discharging gas generated within the heating furnace and/or air circulation means. The gas discharging means may be, for example, a nozzle, a gas pipe, a small hole, or a gas vent valve. The air circulation means may be, for example, a fan or an air conditioner.

In order to efficiently remove organic matter adhering to the glass cloth surface, a continuous method, in which the glass cloth can be heated while being passed through the heating furnace continuously, is more preferable than a batch method, which involves winding the glass fiber fabric around a core and heating the glass cloth at a predetermined ambient temperature.

In order to sufficiently remove organic matter adhering to the surface of the glass cloth, the surface temperature of the glass cloth, as a heating temperature, is preferably higher than 650° C., more preferably 700° C. or higher, further preferably 750° C. or higher, and particularly preferably 800° C. or higher. The surface temperature of the glass cloth can be measured using, for example, a thermocouple or a non-contact thermometer.

### [Contact Member for Heating Glass Cloth]

Although the heating furnace described above may be used as the method for heating the glass cloth, from the viewpoint of low running costs, the glass cloth may also be heated by bringing the glass cloth into contact with a member heated to a predetermined temperature.

Though the shape of the contact member is not particularly limited as long as it can be heated so that the surface temperature of the glass cloth is higher than 650° C., a roll shape is preferable from the viewpoint of ease of conveying the glass cloth. As a member capable of heating glass cloth in the form of a roll, it is preferable to use a roller which is heated by an induction heating method, and which can be used in the high-temperature range and has relatively little variation in temperature in the width direction. When heating the glass cloth with a contact member, it is considered that the temperature of the contact member and the surface temperature of the glass cloth are approximately equal.

In order to remove carbide adhering to the heating roller as the glass cloth is continuously heated, the heating roller method described above is preferably a method having a mechanism for removing contaminants and foreign matter adhering to the roller, such as a mechanism equipped with a blade.

Step (B) of adhering the silane coupling agent can comprise at least one of, for example, a coating step in which a silane coupling agent is caused to adhere to the surface of the glass using a treatment liquid having a concentration of 0.1% by mass to 0.5% by mass, and a fixing step in which the silane coupling agent is fixed to the surface of the glass by heat-drying. In addition, in order to decrease the residues and denatured products of the silane coupling agent which cannot be decreased with water, performing washing with a highly hydrophobic organic solvent or an organic solvent that has a high affinity for residues and denatured products of the silane coupling agent having a hydroxyl group after the fixing step makes it easy to appropriately subject the glass cloth to a surface treatment.

As the method for applying the treatment liquid to glass in the coating step, (a) a method for accumulating the treatment liquid in a bath and immersing and passing the glass therethrough (hereinafter referred to as “immersion method”) or (b) a method for applying the treatment liquid directly to the glass with a roll coater, die coater, gravure coater, etc., may be adopted. In the case of the immersion method, it is preferable to select the immersion time of the glass in the treatment liquid so as to be 0.5 seconds or more and 1 minute or less. Furthermore, after applying the treatment liquid to the glass, the solvent contained in the treatment liquid can be heat-dried using a method such as hot air or electromagnetic waves.

The concentration of the treatment liquid is preferably 0.1% by mass to 0.5% by mass, more preferably 0.1% by mass to 0.45% by mass, and further preferably 0.1% by mass to 0.4% by mass. According to this, it is easy to appropriately subject the glass cloth to a surface treatment.

In the fixing step, the heat-drying temperature is preferably 80° C. or higher, and more preferably 90° C. or higher, so that the reaction between the silane coupling agent and the glass is sufficiently carried out. Further, the heat-drying temperature is preferably 300° C. or lower, and more preferably 180° C. or lower, in order to prevent deterioration of the organic functional groups contained in the silane coupling agent.

As a method for removing silane coupling agent residues and denatured products, known methods such as immersion method and shower spraying may be used, and heating and cooling may be performed as necessary. In order to prevent the dissolved adherents on the glass cloth from re-adhering, it is preferable to decrease excess solvent from the washed glass cloth using a squeezing roller or the like prior to final drying. The organic solvent used is not particularly limited, and examples of highly hydrophobic organic solvents include:
saturated chain aliphatic hydrocarbons such as n-pentane, i-pentane, n-hexane, i-hexane, n-heptane, i-heptane, n-octane, i-octane, 2,2,4-trimethylpentane (isooctane), n-nonane, i-nonane, n-decane, i-decane, and 2,2,4,6,6-pentamethylheptane (isododecane);
saturated cycloaliphatic hydrocarbons such as cyclopentane, cyclohexane, methylcyclohexane, dimethylcyclohexane, and ethylcyclohexane;
aromatic hydrocarbons such as benzene, toluene, xylene, ethylbenzene, diethylbenzene, trimethylbenzene, and triethylbenzene; and
halogen-containing solvents such as chloroform, dichloromethane, and dichloroethane. Examples of organic solvents having a high affinity for denatured products of silane coupling agents include alcohols such as methanol, ethanol and butanol, ketones such as acetone and methyl ethyl ketone, ethers such as methyl ethyl ether and diethyl ether;
amides such as N,N-dimethylformamide and N,N-dimethylacetamide; and
dimethyl sulfoxide. Among these, from the viewpoint of bringing the dissipation factor of the resulting glass cloth near the bulk dissipation factor, aromatic hydrocarbons, alcohols, and ketones are preferable, and methanol is more preferable. Thus, as the washing liquid in the final washing step, it is preferable that a washing liquid in which the main component is methanol (methanol 50% by mass or more, or 60% by mass or more relative to 100% by mass of the washing liquid) be used.

In the final drying step, the amount of washing liquid used in the final washing step can be reduced. The washing liquid used in the final washing step preferably has a boiling point of 120° C. or lower from the viewpoint of ease of decreasing the amount of washing liquid by drying. For drying, heat-drying or blow-drying can be used. When using an organic solvent as the washing liquid, from the viewpoint of safety, it is preferable to perform heat-drying by hot air drying using low-pressure steam or heat medium oil as a heat source. The drying temperature is preferably the boiling point of the washing liquid or higher, and is preferably 180° C. or lower from the viewpoint of suppressing deterioration of the silane coupling agent.

Examples of step (C) of subjecting the glass cloth to an opening treatment include: an opening treatment for applying a water pressure to the obtained glass cloth; an opening treatment with high frequency vibration using water (for example, de-aerated water, ion-exchanged water, deionized water, electrolyzed cationic water, or electrolyzed anionic water) as a medium; a processing treatment using pressure with rollers; processing by dry ice blasting; and processing for bending with a low radius of curvature. Such an opening treatment may be performed simultaneously with weaving or after weaving. It may be performed before or after heat-cleaning, or simultaneously with heat-cleaning, or simultaneously with or after the surface treatment step (B). From the viewpoint of controlling the number of voids five minutes later, when the glass cloth is impregnated with castor oil and the void reduction rate from one minute later to five minutes later, when the glass cloth is impregnated with castor oil, it is necessary to increase the processing force in the opening process, and dry ice blasting processing or bending processing is preferable as the opening method for a glass cloth composed of glass yarns having a high glass hardness.

Dry ice blasting processing is a method in which fine dry ice particles having a particle size of 5 to 300 μm are ejected (sprayed) from a height of 5 to 1000 mm at an air pressure of 0.05 to 1 MPa. More preferably, it is a method in which fine dry ice particles having a particle size of 5 to 300 μm are ejected from a height of 5 mm to 600 mm at an air pressure of 0.1 to 0.5 MPa. By setting within these ranges, the effect of improving the impregnation properties can be secured without causing quality problems such as glass fiber breakage.

The bending processing is a method for subjecting the fibers to opening processing by passing them over a roller having a radius of curvature R=2.5 mm or less, preferably a radius of curvature R=2.0 mm or less, twice or more, and preferably 10 times or more. When the radius of curvature R is 2.5 mm or less, the adhesion between the filaments caused by the sizing agent and the silane coupling agent can be sufficiently removed, and the effect of improving the impregnation properties can be easily secured.

The method for the production of a glass cloth according to the present embodiment can comprise a weaving step of weaving the glass yarns to obtain a glass cloth. The method for the production of a glass cloth according to the present embodiment can comprise the weaving step before the coating step, can comprise the weaving step between the coating step and the final washing step, or can comprise the weaving step after the final washing step.

The method for the production of a glass cloth according to the present embodiment can comprise, if necessary, at least one of:
an adhesive residue decrease step of decreasing denatured products of the sizing agent remaining in the de-sizing step; and
an opening step for opening the glass yarns of the glass cloth after the weaving step.

In the adhesive residue decrease step, dry cleaning such as plasma irradiation and UV ozone; wet cleaning such as high-pressure water washing, organic solvent washing, nanobubble water washing, and ultrasonic water washing; and heat cleaning at a higher temperature than in the heat de-sizing step can be performed, and a plurality of these may be combined. In particular, in the adhesive residue decrease step, it is preferable to perform short-time heat cleaning in which the glass cloth is passed through a heating furnace at 800° C. or higher from roller to roller.

According to the method for the production of a glass cloth of the present embodiment described above, unnecessary components that are thought to increase the dissipation factor are suitably decreased, whereby it becomes easier to apply the silane coupling agent to the surfaces of the individual glass filaments constituting the glass yarns. Furthermore, by strengthening the opening treatment step of the glass fibers, it is possible to improve the heat resistance and insulation reliability of a printed circuit board.

### [Prepreg]

The prepreg according to the present embodiment comprises at least the glass cloth and a matrix resin with which the glass cloth is impregnated. As a result, prepregs having few voids can be provided.

Either of a thermosetting resin or a thermoplastic resin can be used as the matrix resin. If possible, both may be used in combination, and other resins may be further included.

Examples of the thermosetting resin include:
(a) an epoxy resin obtained by adding a compound having an epoxy group and a compound having at least one group selected from the group consisting of an amino group, phenol group, acid anhydride group, hydrazide group, isocyanate group, cyanate group, and hydroxyl group which reacts with the epoxy group;
(b) a radically polymerizable curable resin obtained by curing a compound having at least one group selected from the group consisting of an allyl group, a methacrylic group, and an acrylic group;
(c) a maleimide triazine resin obtained by reacting and curing a compound having a cyanate group and a compound having a maleimide group;
(d) a thermosetting polyimide resin obtained by reacting and curing a maleimide compound and an amine compound; and
(e) a benzoxazine resin obtained by cross-linking and curing a compound having a benzoxazine ring by heat polymerization. Note that to obtain the (a) epoxy resin, the compounds can be reacted without a catalyst, or with the addition of a catalyst having a reaction catalytic ability such as an imidazole compound, a tertiary amine compound, a urea compound, or a phosphorus compound. Furthermore, to obtain the (b) radically polymerizable curable resin, a thermal decomposition catalyst or a photodecomposition catalyst can be used as a reaction initiator.

Examples of the thermoplastic resin include polyphenylene ether, modified polyphenylene ether, polyphenylene sulfide, polysulfone, polyethersulfone, polyarylate, aromatic polyamide, polyetheretherketone, thermoplastic polyimide, insoluble polyimide, polyamideimide, and fluorine resin. As an insulating material for a printed circuit board for high-speed communication, polyphenylene ether or modified polyphenylene ether having high radical reactivity is preferable.

If the matrix resin used for printed circuit boards for high-speed communication has a vinyl group or methacrylic group, silane coupling agents which have a relatively high hydrophobicity and has a functional group that participates in a radical reaction, such as a methacrylic group, are compatible with the matrix resin.

As described above, a thermosetting resin and a thermoplastic resin can be used together. The prepreg can further comprise an inorganic filler. An inorganic filler is preferably used in combination with a thermosetting resin, and examples thereof include aluminum hydroxide, zirconium oxide, calcium carbonate, alumina, mica, aluminum carbonate, magnesium silicate, aluminum silicate, silica, talc, short glass fibers, aluminum borate, and silicon carbide. These inorganic fillers may be used alone or in combination of two or more thereof.

### [Printed Circuit Board]

The printed circuit board according to the present embodiment comprises the prepreg described above. As a result, a printed circuit board having excellent insulation reliability can be provided.

### [Integrated Circuit and Electronic Device]

Furthermore, other aspects of the present embodiment include an integrated circuit and an electronic device comprising the printed circuit board described above. The integrated circuit and electronic device obtained using the printed circuit board according to the present embodiment have excellent various characteristics.

### EXAMPLES

Next, the present invention will be described in detail with reference to Examples and Comparative Examples. However, the invention is not limited by the following Examples.

### [Method for Measuring Basis Weight (Mass of Cloth)]

The basis weight of a cloth is obtained by cutting the cloth to a predetermined size and dividing the mass by the sample area. In the present Examples, the basis weight of each glass cloth is determined by cutting the glass cloth to a size of 10 cm² and measuring the mass.

### [Method for Measuring Converted Thickness]

Since each glass cloth is a discontinuous planar body with air present between the glass fibers, the converted thickness is calculated by dividing the basis weight of the glass cloth (mass of the cloth) by the density. Specifically, the converted thickness is calculated by the following formula (3):

$$Converted thickness ( µm ) = basis weight ( g / {m}^{2} ) / density ( g / {cm}^{3} ) \qquad ( 3 )$$

This converted thickness value is used for measurement using the resonance method.

### [Method for Measuring of Dissipation Factor]

The dissipation factor of each glass cloth is measured in accordance with IEC 62562. Specifically, a glass cloth sample having a size required for measurement using a split cylinder resonator is stored in a constant temperature and humidity oven at 23° C. and 50% RH for 8 hours or more. Thereafter, the dielectric properties of the stored sample are measured using a split cylinder resonator (manufactured by EM Lab) and an impedance analyzer (manufactured by Agilent Technologies). The measurement is performed five times for each sample, and the average value is obtained. The thickness of each sample is measured using the converted thickness described above. Similarly, a glass plate having a thickness of 300 μm or less having the same composition as each glass cloth is prepared, and the bulk dissipation factor is also measured from the thickness value obtained by measuring the thickness of the glass plate. IEC 62562 defines methods for measuring dielectric properties in the microwave band of fine ceramic materials used mainly in microwave circuits.

### [Method for Measuring Loss on Ignition Value of Glass Cloth]

The loss on ignition value of glass loss is determined in accordance with JIS R3420.

### [Method for Measuring Nitrogen Content]

The surface-treated glass cloth is heated at approximately 800° C. for one minute, and the amount of nitrogen dioxide in the generated gas is measured by gas chromatography to determine the amount of nitrogen dioxide in the generated gas. Using, as a reference for comparison, the amount of nitrogen dioxide generated when a predetermined amount of acetanilide (C₈H₉NO) is heated at approximately 800° C. for 1 minute in the same manner, the nitrogen content (% by mass) contained in the surface-treated glass cloth per mass of the glass cloth is determined. A SUMIGRAPH NC-90A (manufactured by Sumika Chemical Analysis Service, Ltd.) is used for the measurement.
Molecular weight of acetanilide=135.17
Nitrogen ratio of acetanilide=10.36%

Specifically, the nitrogen content per mass of the glass cloth is calculated based on the following formula:

$$Nitrogen content per mass of glass cloth =$$

$$[ \{ mass of acetanilide \times ( nitrogen ratio of acetanilide / 100 ) \} /$$

$$peak area derived from nitrogen dioxide generated from acetanilide ] \times$$

$$\{ ( peak area of nitrogen dioxide generated from glass cloth /$$

$$mass of the glass cloth ) \times 100 \}$$

### [Method for Measuring Impregnation Properties]

The glass cloth is sampled so as to have a size of 50 mm×50 mm or more. At this time, sampling is performed without bending or touching the measurement locations. Evaluation is performed by counting the number of voids when the sampled glass cloth is impregnated with castor oil (manufactured by Hayashi Pure Chemical Industries, Ltd.) a predetermined period of time at a liquid temperature of 24 to 26° C. A high-precision camera (frame size: 5120×5120 pixels) is installed in a vertical position relative to the glass cloth, and the glass cloth is irradiated at both sides thereof with LED lights (power flash bar lighting manufactured by CCS Co., Ltd.) used as a light source, the LED lights positioned directly alongside and 15 cm away from the glass cloth so as to sandwich the glass cloth. At a viewing angle of 32 mm×32 mm, the number of voids of 160 μm or more present between the glass filaments is counted, and the average value of three measurements is taken as the number of voids. The voids correspond to portions unimpregnated with the matrix resin. Thus, a small number of voids in the glass cloth means that the glass cloth has excellent impregnation properties with the matrix resin.

The “void reduction rate (%) from one minute later to five minutes later when impregnating the glass cloth with castor oil” is calculated using the formula:

$$“ \{ ( A - B ) / A \} \times 100 ( \% ) ”$$

where A is the number of voids in the glass cloth when impregnated with castor oil for one minute, and B is the number of voids in the glass cloth when impregnated with castor oil for five minutes.

### [Glass Cloth]

### (Gray Glass Fabric A)

Using glass yarns having an SiO₂ composition amount of more than 99.9% by mass, a cloth was woven using an air jet loom at a weaving density of 66 warps/25 mm and 68 wefts/25 mm. Silica glass yarns having an average filament diameter of 5.0 μm, a filament number of 100, and a twist number of 1.0 Z were used as the warp yarns. Silica glass yarns having an average filament diameter of 5.0 μm, a filament number of 100, and a twist number of 1.0 Z were used as the weft yarns.

### (Gray Glass Fabric B)

Using glass yarns having an SiO₂ composition amount of more than 99.9% by mass, a cloth was woven using an air jet loom at a weaving density of 54 warps/25 mm and 54 wefts/25 mm. Note that weaving was performed so that the cloth width was 1300 mm. Silica glass yarns having an average filament diameter of 5.0 μm, a filament number of 200, and a twist number of 1.0 Z were used as the warp yarns. Silica glass yarns having an average filament diameter of 5.0 μm, a filament number of 200, and a twist number of 1.0 Z were used as the weft yarns.

### (Gray Glass Fabric C)

A cloth was woven using E-glass yarns at a weaving density of 66 warps/25 mm and 68 wefts/25 mm. E glass yarns having an average filament diameter of 5.0 μm, a filament number of 100, and a twist number of 1.0 Z were used as the warp yarns. E glass yarns having an average filament diameter of 5.0 μm, a filament number of 100, and a twist number of 1.0 Z were used as the weft yarns.

### Example 1

Gray glass fabric A was heat-treated at 900° C. for 60 seconds for de-sizing (heating de-oiling step). Next, a treatment liquid was adjusted by dispersing 0.3% by mass of 3-methacryloxypropyltrimethoxysilane (silane coupling agent A); Z6030 (manufactured by Dow Toray Industries, Inc.) in pure water adjusted to pH=3 with acetic acid. The cloth was immersed in the treatment liquid at a line speed of 1.5 m/min, squeezed to remove the liquid, and thereafter dried by heating at 130° C. for 60 seconds to fix the silane coupling agent (fixing step). The dried cloth was irradiated with ultrasonic waves at a frequency of 25 kHz and an output of 0.50 W/cm² in water to decrease the excess silane coupling agent physically adhered to the cloth (washing step), and then dried by heating at 130° C. for one minute (drying step). Thereafter, dry ice fine particles of 5 to 50 μm were uniformly sprayed over the entire glass cloth at an air pressure of 0.4 MPa to perform an opening treatment (opening treatment using dry ice blasting), whereby a glass cloth was obtained. After calculating the converted thickness from the basis weight and density of the obtained glass cloth, the dissipation factor of the glass cloth was measured.

### Example 2

Gray glass fabric A was heat-treated at 600° C. for 60 seconds for de-sizing. Next, a treatment liquid was adjusted by dispersing 0.1% by mass of 3-methacryloxypropyltrimethoxysilane (silane coupling agent A); Z6030 (manufactured by Dow Toray Industries, Inc.) in pure water adjusted to pH=3 with acetic acid. The cloth was immersed in the treatment liquid at a line speed of 1.5 m/min, squeezed to remove the liquid, and thereafter dried by heating at 130° C. for 60 seconds to fix the silane coupling agent. The dried cloth was irradiated with ultrasonic waves at a frequency of 25 kHz and an output of 0.50 W/cm² in water to decrease the excess silane coupling agent physically adhered to the cloth, and then dried by heating at 130° C. for one minute. Thereafter, dry ice fine particles of 5 to 50 μm were uniformly sprayed over the entire glass cloth at an air pressure of 0.5 MPa to perform opening treatment, whereby a glass cloth was obtained. After calculating the converted thickness from the basis weight and density of the obtained glass cloth, the dissipation factor of the glass cloth was measured.

### Example 3

Gray glass fabric A was heat-treated at 900° C. for 60 seconds for de-sizing. Next, a treatment liquid was adjusted by dispersing 0.3% by mass of 5-hexenyltrimethoxysilane (silane coupling agent B); Z6161 (manufactured by Dow Toray Industries, Inc.) in pure water adjusted to pH=3 with acetic acid. The cloth was immersed in the treatment liquid at a line speed of 1.5 m/min, squeezed to remove the liquid, and thereafter dried by heating at 130° C. for 60 seconds to fix the silane coupling agent. The dried cloth was irradiated with ultrasonic waves at a frequency of 25 kHz and an output of 0.50 W/cm² in water to decrease the excess silane coupling agent physically adhered to the cloth, and then dried by heating at 130° C. for one minute. Thereafter, dry ice fine particles of 5 to 50 μm were uniformly sprayed over the entire glass cloth at an air pressure of 0.5 MPa to perform opening treatment, whereby a glass cloth was obtained. After calculating the converted thickness from the basis weight and density of the obtained glass cloth, the dissipation factor of the glass cloth was measured.

### Example 4

Gray glass fabric A was heat-treated at 900° C. for 60 seconds for de-sizing. Next, a treatment liquid was adjusted by dispersing 0.15% by mass of 3-methacryloxypropyltrimethoxysilane (silane coupling agent A); Z6030 (manufactured by Dow Toray Industries, Inc.) and 0.15% by mass of 5-hexenyltrimethoxysilane (silane coupling agent B); Z6161 (manufactured by Dow Toray Industries, Inc.) in pure water adjusted to pH=3 with acetic acid. The cloth was immersed in the treatment liquid at a line speed of 1.5 m/min, squeezed to remove the liquid, and thereafter dried by heating at 130° C. for 60 seconds to fix the silane coupling agent. The dried cloth was irradiated with ultrasonic waves at a frequency of 25 kHz and an output of 0.50 W/cm² in water to decrease the excess silane coupling agent physically adhered to the cloth, and then dried by heating at 130° C. for one minute. Thereafter, dry ice fine particles of 5 to 50 μm were uniformly sprayed over the entire glass cloth at an air pressure of 0.2 MPa to perform opening treatment, whereby a glass cloth was obtained. After calculating the converted thickness from the basis weight and density of the obtained glass cloth, the dissipation factor of the glass cloth was measured.

### Example 5

A glass cloth was obtained in the same manner as in Example 1, except that the solvent used in the ultrasonic washing was changed from water to methanol. After calculating the converted thickness from the basis weight and density of the obtained glass cloth, the dissipation factor of the glass cloth was measured.

### Example 6

Gray glass fabric B was heat-treated at 1000° C. for 20 seconds for de-sizing. Next, a treatment liquid was adjusted by dispersing 0.15% by mass of 3-methacryloxypropyltrimethoxysilane (silane coupling agent A); Z6030 (manufactured by Dow Toray Industries, Inc.) in pure water adjusted to pH=3 with acetic acid. The cloth was immersed in the treatment liquid at a line speed of 1.5 m/min, squeezed to remove the liquid, and thereafter dried by heating at 130° C. for 60 seconds to fix the silane coupling agent. The dried cloth was irradiated with ultrasonic waves at a frequency of 25 kHz and an output of 0.50 W/cm² in a methanol solvent to decrease the excess silane coupling agent physically adhered to the cloth, and then dried by heating at 130° C. for one minute. Thereafter, dry ice fine particles of 5 to 50 μm were uniformly sprayed over the entire glass cloth at an air pressure of 0.45 MPa to perform opening treatment, whereby a glass cloth was obtained. After calculating the converted thickness from the basis weight and density of the obtained glass cloth, the dissipation factor of the glass cloth was measured.

### Comparative Example 1

A glass cloth was obtained in the same manner as in Example 1, except that the concentration of the treatment liquid was changed to 0.7% by mass and the opening treatment by dry ice blasting was not performed. After calculating the converted thickness from the basis weight and density of the obtained glass cloth, the dissipation factor of the glass cloth was measured.

### Comparative Example 2

A glass cloth was obtained in the same manner as in Example 1, except that the concentration of the treatment liquid was changed to 0.04% by mass and the opening treatment by dry ice blasting was not performed. After calculating the converted thickness from the basis weight and density of the obtained glass cloth, the dissipation factor of the glass cloth was measured.

### Comparative Example 3

A glass cloth was obtained in the same manner as in Example 1, except that a treatment liquid in which 0.15% by mass of N-β-(N-vinylbenzylaminoethyl)-γ-aminopropyltrimethoxysilane hydrochloride (silane coupling agent C); Z6032 (manufactured by Dow Toray Industries, Inc.) was dispersed was used and the opening treatment by dry ice blasting was not performed. After calculating the converted thickness from the basis weight and density of the obtained glass cloth, the dissipation factor of the glass cloth was measured.

### Comparative Example 4

A glass cloth was obtained in the same manner as in Comparative Example 3, except that the concentration of the treatment liquid was 0.35% by mass and the opening treatment by dry ice blasting was not performed. After calculating the converted thickness from the basis weight and density of the obtained glass cloth, the dissipation factor of the glass cloth was measured.

### Comparative Example 5

A glass cloth was obtained in the same manner as in Example 1, except that the opening processing was performed using a columnar flow discharged from a 1.4 MPa high-pressure water spray. After calculating the converted thickness from the basis weight and density of the obtained glass cloth, the dissipation factor of the glass cloth was measured.

### Comparative Example 6

A glass cloth was obtained in the same manner as in Example 1, except that gray glass fabric C was used and heat de-oiling was performed at 400° C. for 72 hours. After calculating the converted thickness from the basis weight and density of the obtained glass cloth, the dissipation factor of the glass cloth was measured.

### [Method for Production of Laminate]

For each of the glass cloths obtained in the Examples and Comparative Examples, a varnish was prepared by adding 45 parts by mass of polyphenylene ether (manufactured by SABIC, SA9000), 10 parts by mass of triallylisocyanurate, 45 parts by mass of toluene, and 0.6 parts by mass of 1,3-di(tert-butylisopropylbenzene) to a stainless-steel container and stirring at room temperature for 1 hour. The glass cloths were impregnated with the prepared varnish and then dried at 115° C. for one minute to obtain prepregs. Eight of the obtained prepregs were stacked, and copper foils having a thickness of 12 μm were stacked on the top and bottom thereof, and the stack was heated and pressed at 200° C. and 40 kg/cm² for 120 minutes to obtain a laminate.

### [Method for Evaluating Heat Resistance of Laminate]

After removing the copper foils from the laminate obtained as described above, the laminate was heated and water was absorbed therein in a pressure cooker at 133° C. for 62 hours. The laminate after water-absorption was immersed in a solder bath at 288° C. for 20 seconds, and the presence or absence of blisters caused by peeling at the interface between the glass cloth and the resin was visually confirmed. Four tests were performed on each glass cloth. In Table 2, the evaluation of heat resistance is as follows. Note that the less the blistering of the glass cloth, the better the heat resistance thereof.
E (Excellent): There was no blistering in all of the four laminates.
G (Good): Blisters were present in one or two laminates.
P (Poor): Blisters were present in 3 or 4 laminates.

### [Method for Evaluating Insulation Reliability of Laminate]

A laminate having a thickness of 1.0 mm was prepared as described above, and a circuit pattern having through holes arranged at 0.30 mm intervals was prepared on the copper foil on both sides of the laminate to obtain an insulation reliability evaluation sample. A voltage of 50 V was applied to the obtained sample in the atmosphere at a temperature of 85° C. and a humidity of 85% RH, and the change in resistance value was measured. At this time, the case where the resistance became less than 1 MΩ within 500 hours after the start of the test was evaluated as an insulation failure. The same measurements were performed on 10 samples, and the number of samples that did not suffer from insulation defects among the 10 samples was determined.

Table 2 shows the production conditions and evaluation results of the Examples and Comparative Examples. Note that the prepregs and printed circuit boards of each of the glass cloths of Examples 1 to 6 could be produced by a conventional method.

TABLE 2

| | | | | | | | Comp |
|---|---|---|---|---|---|---|---|
| | Ex 1 | Ex 2 | Ex 3 | Ex 4 | Ex 5 | Ex 6 | Ex 1 |
| Gray glass fabric | A | A | A | A | A | B | A |
| Heating | 900° C. - | 600° C. - | 900° C. - | 900° C. - | 900° C. - | 1000° C. - | 600° C. - |
| de-oiling step | 60 sec | 60 sec | 60 sec | 60 sec | 60 sec | 20 sec | 60 sec |
| Fixing step | 130° C. - | 130° C. - | 130° C. - | 130° C. - | 130° C. - | 130° C. - | 130° C. - |
| | 1 min | 1 min | 1 min | 1 min | 1 min | 1 min | 1 min |
| Washing step | Water | Water | Water | Water | Methanol | Methanol | Water |
| | washing | washing | washing | washing | washing | washing | washing |
| Drying step | 130° C. - | 130° C. - | 130° C. - | 130° C. - | 130° C. - | 130° C. - | 130° C. - |
| | 1 min | 1 min | 1 min | 1 min | 1 min | 1 min | 1 min |
| Opening step | Dry ice | Dry ice | Dry ice | Dry ice | Dry ice | Dry ice | — |
| | blasting | blasting | blasting | blasting | blasting | blasting | |
| Silane coupling | A | A | B | A, B | A | A | A |
| agent type | | | | | | | |
| Loss on ignition | 0.07 | 0.03 | 0.08 | 0.10 | 0.07 | 0.05 | 0.13 |
| value of glass | | | | | | | |
| cloth (% by mass) | | | | | | | |
| Nitrogen content | <0 | <0 | <0 | <0 | <0 | <0 | <0 |
| of glass cloth | | | | | | | |
| (% by mass) | | | | | | | |
| Bulk dissipation | 0.0002 | 0.0002 | 0.0002 | 0.0002 | 0.0002 | 0.0002 | 0.0002 |
| factor of glass | | | | | | | |
| @10 GHz | | | | | | | |
| Dissipation | 0.000255 | 0.000341 | 0.000292 | 0.000350 | 0.000215 | 0.000179 | 0.000487 |
| factor of glass | | | | | | | |
| cloth @10 GHz | | | | | | | |
| Number of voids | 112 | 93 | 85 | 155 | 102 | 108 | 259 |
| 5 minutes later | | | | | | | |
| Void reduction | 86 | 95 | 89 | 76 | 88 | 87 | 51 |
| rate (%) from | | | | | | | |
| 1 minute later to | | | | | | | |
| 5 minutes later | | | | | | | |
| Heat resistance | E | E | E | E | E | E | E |
| evaluation of | (Exc) | (Exc) | (Exc) | (Exc) | (Exc) | (Exc) | (Exc) |
| laminated | | | | | | | |
| substrate | | | | | | | |
| Insulation | 9 | 6 | 9 | 8 | 8 | 9 | 2 |
| reliability of | | | | | | | |
| laminated | | | | | | | |
| substrate | | | | | | | |

| | Comp | Comp | Comp | Comp | Comp |
|---|---|---|---|---|---|
| | Ex 2 | Ex 3 | Ex 4 | Ex 5 | Ex 6 |
| Gray glass fabric | A | A | A | A | C |
| Heating | 600° C. - | 900° C. - | 900° C. - | 900° C. - | 400° C. - |
| de-oiling step | 60 sec | 60 sec | 60 sec | 60 sec | 72 hr |
| Fixing step | 130° C. - | 130° C. - | 130° C. - | 130° C. - | 130° C. - |
| | 1 min | 1 min | 1 min | 1 min | 1 min |
| Washing step | Water | Water | Water | Water | Water |
| | washing | washing | washing | washing | washing |
| Drying step | 130° C. - | 130° C. - | 130° C. - | 130° C. - | 130° C. - |
| | 1 min | 1 min | 1 min | 1 min | 1 min |
| Opening step | — | — | — | Spraying | Dry ice |
| | | | | | blasting |
| Silane coupling | A | C | C | A | C |
| agent type | | | | | |
| Loss on ignition | 0.005 | 0.08 | 0.18 | 0.09 | 0.10 |
| value of glass | | | | | |
| cloth (% by mass) | | | | | |
| Nitrogen content | <0 | 0.008 | 0.02 | <0 | <0 |
| of glass cloth | | | | | |
| (% by mass) | | | | | |
| Bulk dissipation | 0.0002 | 0.0002 | 0.0002 | 0.0002 | 0.0066 |
| factor of glass | | | | | |
| @10 GHz | | | | | |
| Dissipation | 0.000287 | 0.000322 | 0.000489 | 0.000290 | 0.006820 |
| factor of glass | | | | | |
| cloth @10 GHz | | | | | |
| Number of voids | 239 | 221 | 236 | 190 | 139 |
| 5 minutes later | | | | | |
| Void reduction | 54 | 43 | 46 | 62 | 83 |
| rate (%) from | | | | | |
| 1 minute later to | | | | | |
| 5 minutes later | | | | | |
| Heat resistance | P | P | E | E | E |
| evaluation of | (Poor) | (Poor) | (Exc) | (Exc) | (Exc) |
| laminated | | | | | |
| substrate | | | | | |
| Insulation | 0 | 1 | 1 | 3 | 8 |
| reliability of | | | | | |
| laminated | | | | | |
| substrate | | | | | |

1. A glass cloth, comprising woven glass yarns, wherein
a bulk dissipation factor of a glass constituting the glass yarns is 0.0010 or less,
a loss on ignition value of the glass cloth is 0.01% by mass or more and less than 0.12% by mass, and
a void number five minutes later is 180 or less when the glass cloth is impregnated with castor oil.

2. The glass cloth according to claim 1, wherein a void reduction rate from one minute later to five minutes later is 70% or more when the glass cloth is impregnated with castor oil.

3. A glass cloth, comprising woven glass yarns, wherein
a bulk dissipation factor of a glass constituting the glass yarns is 0.0010 or less,
a loss on ignition value of the glass cloth is 0.01% by mass or more and less than 0.12% by mass, and
a void reduction rate from one minute later to five minutes later is 70% or more when the glass cloth is impregnated with castor oil.

4. The glass cloth according to claim 1, wherein a void number five minutes later is 160 or less, when the glass cloth is impregnated with castor oil.

5. The glass cloth according to claim 2, wherein a void reduction rate from one minute later to five minutes later is 80% or more, when the glass cloth is impregnated with castor oil.

6. The glass cloth according to claim 1, wherein the bulk dissipation factor of the glass constituting the glass yarns is 0.0008 or less.

7. The glass cloth according to claim 1, wherein a silicon (Si) content of the glass yarns is 95.0% by mass to 100% by mass in terms of silicon dioxide (SiO₂).

8. The glass cloth according to claim 1, wherein a silicon (Si) content of the glass yarns is 99.0% by mass to 100% by mass in terms of silicon dioxide (SiO₂).

9. The glass cloth according to claim 1, which is subjected to a surface treatment.

10. The glass cloth according to claim 9, wherein the surface treatment is a treatment with a silane coupling agent having a structure represented by the following general formula (1):
X(R)₃₋ₙSiYₙ (1)
where X is an organic functional group having one or more radical-reactive unsaturated double bond groups,
each Y is independently an alkoxy group,
n is an integer from 1 to 3, and
each R is independently at least one of a methyl group, an ethyl group, and a phenyl group.

11. The glass cloth according to claim 10, wherein X in formula (1) does not contain an amino group and contains a (meth)acryloxy group.

12. The glass cloth according to claim 1, wherein a loss on ignition value of the glass cloth is 0.10% by mass or less.

13. The glass cloth according to claim 1, wherein a nitrogen content per mass is less than 0.004% by mass.

14. The glass cloth according to claim 1, wherein a dissipation factor of the glass cloth at 10 GHz as measured by a resonance method is greater than 0 and 0.0008. or less.

15. The glass cloth according to claim 1, wherein a dissipation factor of the glass cloth at 10 GHz as measured by a resonance method is greater than 0 and 0.0005 or less.

16. A prepreg, comprising the glass cloth according to claim 1, and a matrix resin with which the glass cloth is impregnated.

17. The prepreg according to claim 16, further comprising an inorganic filler.

18. A printed circuit board, comprising the prepreg according to claim 16.

19. An integrated circuit, comprising the printed circuit board according to claim 18.

20. An electronic device, comprising the printed circuit board according to claim 18.

21. The glass cloth according to claim 3, wherein a void reduction rate from one minute later to five minutes later is 80% or more, when the glass cloth is impregnated with castor oil.

22. The glass cloth according to claim 3, wherein the bulk dissipation factor of the glass constituting the glass yarns is 0.0008 or less.

23. The glass cloth according to claim 3, wherein a silicon (Si) content of the glass yarns is 95.0% by mass to 100% by mass in terms of silicon dioxide (SiO₂).

24. The glass cloth according to claim 3, wherein a silicon (Si) content of the glass yarns is 99.0% by mass to 100% by mass in terms of silicon dioxide (SiO₂).

25. The glass cloth according to claim 3, which is subjected to a surface treatment.

26. The glass cloth according to claim 25, wherein the surface treatment is a treatment with a silane coupling agent having a structure represented by the following general formula (1):
X(R)₃₋ₙSiYₙ (1)
where X is an organic functional group having one or more radical-reactive unsaturated double bond groups,
each Y is independently an alkoxy group,
n is an integer from 1 to 3, and
each R is independently at least one of a methyl group, an ethyl group, and a phenyl group.

27. The glass cloth according to claim 26 wherein X in formula (1) does not contain an amino group and contains a (meth)acryloxy group.

28. The glass cloth according to claim 3, wherein a loss on ignition value of the glass cloth is 0.10% by mass or less.

29. The glass cloth according to claim 3, wherein a nitrogen content per mass is less than 0.004% by mass.

30. The glass cloth according to claim 3, wherein a dissipation factor of the glass cloth at 10 GHz as measured by a resonance method is greater than 0 and 0.0008. or less.

31. The glass cloth according to claim 3, wherein a dissipation factor of the glass cloth at 10 GHz as measured by a resonance method is greater than 0 and 0.0005 or less.

32. A prepreg, comprising the glass cloth according to claim 3, and a matrix resin with which the glass cloth is impregnated.

33. The prepreg according to claim 32, further comprising an inorganic filler.

34. A printed circuit board, comprising the prepreg according to claim 32.

35. An integrated circuit, comprising the printed circuit board according to claim 34.

36. An electronic device, comprising the printed circuit board according to claim 34.
